(19) United States
(12) Patent Application Publication
(10) Pub. No.: US 2012/0152608 A1
(43) Pub. Date: Jun. 21, 2012

(54) PRINTED CIRCUIT BOARD WITH A SCREEN

(75) Inventors: Alexander Weigel, Wilhermsdorf (DE); Mario Mitzel, Nuernberg (DE)

(73) Assignee: Semikron Elektronik GmbH & Ko. KG, Nurnberg (DE)

(21) Appl. No.: 13/329,209

(22) Filed: Dec. 16, 2011

(30) Foreign Application Priority Data
Dec. 16, 2010 (DE) 10 2010 063 245.7

(51) Int. Cl. H05K 9/00

(52) U.S. Cl. 174/350

(57) ABSTRACT

A printed circuit board having a generally box-like carrier plate with a top side and an underside. The board has at least first and second conductor track plane separated by a first distance and an electrical circuit which occupies at least one section of the carrier plate. The section contains a screen for protecting the circuit from electromagnetic interference. The screen has a first screening conductor track which is arranged on the first conductor track plane and surrounds the section, and a second screening conductor track which is arranged on the second conductor track plane and also surrounds the section. The first and second screening conductor tracks are congruent at least in a circumferential region which surrounds the circuit. The screen has, in the circumferential region, a plurality of plated-through holes which penetrate the carrier plate and connect the first and second screening conductor tracks.

### BACKGROUND OF THE INVENTION

1. Field of the Invention

The invention relates to a printed circuit board having a screen for screening out electromagnetic interference.

2. Description of the Related Art

Printed circuit boards such as are the subject of the instant inventionare commonly used to construct electrical circuits and have a carrier plate having a top side and an underside. A carrier plate generally has the form of a very thin box which extends in a planar manner and the flat sides of which then form the top side and the underside. For example, at least one of the top side and the underside is fitted with components. In the case of conventional components, their connections or connecting wires penetrate the carrier plate. In contrast, SMD (surface mounted device) components are arranged only directly on the surface, that is to say on the top side or underside. Electrical conductor tracks which connect the connections of the components are fitted on the top side and underside. Further electrical connections between the top side and underside are produced with the aid of plated-through holes between two sections of conductor tracks which lie above one another. Multilayer printed circuit boards in which one or more conductor track planes are also arranged inside the carrier plate are also known. All of the conductor track planes as well as the top side and underside are generally parallel to on another.

Switching events of the circuits on the printed circuit board produce electromagnetic interference inside the printed circuit board. These are also referred to as EMC (electromagnetic compatibility) events. The interference is emitted to the environment; in other words, coupling-out interference is produced. Conversely, interference occurring outside the printed circuit board may also trigger undesirable EMC effects on the circuits of the printed circuit board and, may interfere with the function of the circuits for a long time. The elktrical circuit therefore needs to be screened from the environment with the aid of a screening apparatus (referred to as (EMC) screen for short) which protects against electromagnetic interference. Without such an EMC screen, interference can be easily coupled into the printed circuit board or circuit from the outside and may interfere with sensitive signal lines, that is to say the electrical signals on the conductor tracks. Other devices may also be disrupted by such interference.

The screen need not be completely arranged around the entire printed circuit board or its entire wiring but can also be arranged only between partial circuits, that is to say parts of an entire circuit, which are sensitive to EMC interference in order to improve the EMC behavior of the entire printed circuit board. This is important, for example, for a drive circuit for a power semiconductor switch, such as an IGBT (insulated gate bipolar transistor) or MOSFET (metal oxide semiconductor field effect transistor), in order to safely isolate a primary side having low voltages from a secondary side having sometimes very high voltages. In this case, voltages may be up to 1700 V. The primary side and the secondary side then correspond to individual partial circuits on a common printed circuit board, each of which needs to be provided with a screen.

Different screens are known for this purpose. For example, one embodiment in which the circumferential edge of the printed circuit board, i.e., that edge of the printed circuit board which respectively jointly bounds the top side and the underside, is metallized as a screen is known. This improves the EMC behavior of the printed circuit board and provides a simultaneous additional heat dissipation option and an additional ground (GND) on the edge of the printed circuit board.

In the known embodiment, the metallization applied to or over the edge of the printed circuit board may be easily detached from the carrier plate when handling the printed circuit board. In addition, the corners of the printed circuit board, where two edges meet, are not metallized here during production. A gap in the EMC screen is therefore produced in that location.

There is therefore a need for a better way to protect printed circuit boards from interference.

### SUMMARY OF THE INVENTION

It is therefore an object of the invention to provide an improved printed circuit board having a screen.

In accordance with this object, there is provided a printed circuit board having a carrier plate which has a top side and an underside. The printed circuit board contains an electrical circuit, i.e., generally components and conductor tracks, which occupies at least one section of the carrier plate. In this case, the section comprises a congruent partial surface of the top side and the underside and the volume of the carrier plate therebetween. In other words, components and conductor tracks of the circuit are thus present at least on a partial surface of the printed circuit board. The printed circuit board also contains at least first and second conductor track planes separated by a distance. The conductor track planes may be situated on the top side and/or underside or even inside the printed circuit board. Further conductor track planes may be present. The conductor tracks of the circuit are arranged on the conductor track planes. Under certain circumstances, plated-through holes which connect the conductor tracks or components on different conductor track planes may also be provided.

The printed circuit board also has a screen according to the invention which screens the circuit from electromagnetic radiation. The screen contains a first screening conductor track which is arranged on the first conductor track plane and substantially completely surrounds that section of the carrier plate which is occupied by the circuit. The screen also contains a second screening conductor track which is arranged on the second conductor track plane and likewise substantially completely surrounds the section. The first and second screening conductor tracks are congruent with respect to the printed circuit board, that is to say are offset with respect to one another perpendicular to the top side and underside of the printed circuit board, at least in a circumferential region which likewise bounds the circuit or the section in a closed manner.

In other words, at least parts of the first and second screening conductor tracks lie above one another in a congruent manner on the first and second conductor track planes in the circumferential region. The screen also has a plurality of plated-through holes which each penetrate the substrate—generally perpendicular to the top side/underside—and each provide an electrical connection between the first and second screening conductor tracks. All of the plated-through holes are in the circumferential region and likewise surround the section in their entirety.

Plated-through vias, that is to say plated-through holes, are thus placed at distances of typically about 0.5 to about 5 mm, for example, along the entire screen, i.e., along the entire upper and lower screening conductor tracks in the circumferential region, to electrically connect the upper and lower (first and second) screening conductor tracks. The plated-through holes generally run perpendicular to the top side and the underside and have at least a height which extends from the first conductor track plane to the second conductor track plane, but they generally penetrate the entire height or thickness of the printed circuit board.

The first and second screening conductor tracks thus form, together with the plated-through holes, a type of ring around the circuit or section that constitutes a screen, i.e., the apparatus for screening the circuit from electromagnetic radiation. The first and second screening conductor tracks thus surround the section at different height or thickness positions of the printed circuit board. The first and second screening conductor tracks and the plated-through holes are electrically conductive structures, for example made of copper, aluminum or other electrically conductive materials.

In the case of the inventive printed circuit board, the described screen which surrounds substantially the entire circuit in the region of the printed circuit board reduces and, in the best-case scenario, entirely blocks, interference precisely there. Use of the screen of the inventive printed circuit board results in improved attenuation or elimination of coupling-in or coupling-out interference.

In other words, the screen forms a grid which penetrates the printed circuit board in a virtually vertical manner from the first conductor track plane to the second conductor track plane and completely surrounds the circuit and, in particular, its conductor tracks. Since interference is generally coupled in and radiated mainly in the region of the printed circuit board and there at the edge which bounds the circuit or the section, transmission of the radiation (in or out) is prevented in a particularly effective manner.

In one simple embodiment, the first conductor track plane is arranged on the top side and the second conductor track plane is arranged on the underside of the printed circuit board. The screen then extends over the entire height or thickness of the carrier plate from the top side to the underside.

As mentioned above, a printed circuit board may have at least one further conductor track plane which is arranged between the top side and the underside. This is thus a so-called multilayer printed circuit board having not only conductor tracks which are exposed on the top side and underside, for example, but also a plurality of conductor track planes in the interior. Printed circuit boards with up to twenty internal conductor track planes or conductor layers are known in this case.

In this case, two screening conductor tracks may furthermore be arranged on the top side and underside or on intermediate layers at a distance from one another. The conductor track planes between the two planes bearing the screening conductor tracks then need not necessarily have their own third or further screening conductor tracks. In this case, the distances between the first and second screening conductor tracks are generally small enough to produce the desired screening effect against interference, even for conductor track planes in between.

However, in one advantageous embodiment, a further screening conductor track which corresponds to the first and second screening conductor tracks insofar as it also covers the circumferential region is also situated in the at least one further conductor track plane. Each further screening conductor track is then also likewise connected to the plated-through holes. In other words, the screen is thus also extended to the intermediate layers of a multilayer printed circuit board. In other words, in the case of multilayer printed circuit boards, screening conductor tracks which run around in the interior and correspond to the first and second screening conductor tracks can also be fitted and are then likewise electrically incorporated in the screen with the aid of the plated-through holes.

A conductor track plane may also contain exclusively a screening conductor track associated with the screen, that is to say a screening line. The signal-carrying conductor tracks of the circuit are then arranged in other conductor track planes.

In this advantageous embodiment, at least one of the conductor track planes is a ground layer which fills the entire surface of at least the section. In this case, the term “entire surface” means that, for example, only passage regions, for example for vias or connecting lines of components, are left out of the entire surface so that such lines can pass through the ground layer in a vertical manner without coming into contact with the latter. In other words, the annular screening conductor track of this plane degenerates to form a ground layer over the entire surface.

A corresponding printed circuit board will generally then have a plurality of layers, the conductor track plane closest to the top side and underside in each case being in the form of a ground layer over the entire surface in the above sense, for example. Further conductor track planes are then fitted between two ground layers. The ground layers above and below these signal-carrying layers then completely screen the latter from the environment. The ground layers connected to the screen thus supplement the latter to form a cage which completely encapsulates the intermediate layers. Only the abovementioned passage regions result as passage points from the cage.

Such printed circuit boards thus have a multilayer structure, under certain circumstances with a plurality of ground layers which, under certain circumstances, are connected to ground potential (GND). All of the ground layers are generally connected to one another by means of the screen or the plated-through holes. This prevents a ground default of individual ground layers with respect to one another and further improves screening against interference.

In other words, two ground layers which are at a distance from one another and the plated-through holes which are distributed in a cage-like manner and connect the ground layers, for example, thus produce a screen or screening apparatus which actually reliably screens the entire circuit between the ground layers and inside the screen from interference, and interference on account of EMC effects is thus avoided.

In particular, the first and second screening conductor tracks can then each degenerate to form a ground layer which is respectively inside the carrier plate, for example. The abovementioned complete screening or cage effect then results together with the plated-through holes.

In one preferred embodiment, the screen is a screen which is arranged in the edge region of the printed circuit board and completely encircles the printed circuit board. All circuit parts or partial circuits present on the printed circuit board are thus completely surrounded. Placing the screen at the edge of the circuit or printed circuit board can also be effective as additional ESD (electrostatic discharge) protection from contact. For example, the first and second screening conductor tracks can be found on the top side and underside of the printed circuit board and are not electrically insulated from one another. When the subassembly is touched by the fingers of a user, for example, it then comes into conductive contact with the user. Potential equalization between the user and the printed circuit board or its ground potential is thus established, which results in safe handling.

However, the first and second screening conductor tracks could be easily damaged when handling the printed circuit board when said conductor tracks are arranged on the top side and underside. In order to prevent this, the first and second screening conductor tracks cannot then be entirely routed to the edge of the printed circuit board but rather can also be surrounded by a small spacer region. For example, a spacer region having a width of approximately 1 mm is thus left free at the edge on the top side and underside of the printed circuit board, that is to say the first and second screening conductor tracks are each placed at a distance of about 1 mm from the edge as screening conductor tracks which likewise have a width of about 1 mm, for example. However, edge spacings and widths of the screening conductor tracks may vary in this case.

In one preferred embodiment of the invention, the screen is connected to a ground potential. The entire screen is grounded, for example, when the screen is connected to a ground potential GND. Alternatively, however, the screen could also not be connected to a ground potential but rather could be completely electrically insulated; this is referred to as a floating screen, the potential of which is thus not electrically fixed in any way with respect to any other potential.

In another embodiment of the invention, a plurality of electrical circuits which each occupy a section of the carrier plate exist on the printed circuit board. In this case, each of the circuits may now also have its own screen which respectively surrounds the circuits. Circuits which are screened from one another in sections of the carrier plate inside a printed circuit board also cannot electromagnetically interfere with one another.

In a further preferred embodiment of the invention, the distance between two adjacent plated-through holes is at least approximately the distance between two adjacent conductor track planes. In particular, the shortest distance occurring on the printed circuit board between two conductor track planes can be selected in this case.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

In the drawings, which, in each case is a schematic outline sketch:

FIG. 1 shows a printed circuit board with a screen according to the invention;

FIG. 2 shows a plan view of the printed circuit board from FIG. 1;

FIG. 3 shows an alternative printed circuit board in detail;

FIG. 4 shows a plan view of an alternative printed circuit board;

FIG. 5 shows a section through a screen; and

FIG. 6 shows an alternative printed circuit board having a plurality of conductor track planes.

### DETAILED DESCRIPTION OF THE PRESENTLY PREFERRED EMBODIMENTS

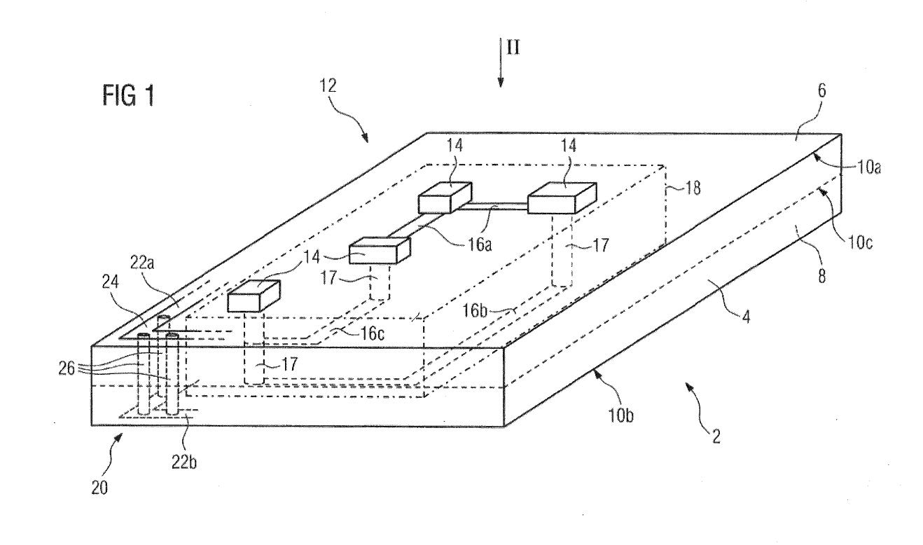

FIG. 1 shows a printed circuit board 2 containing a carrier plate 4 which has a top side 6 and an underside 8. Carrier plate 4 is generally planar, so that it extends in a two-dimensions, in the manner of a flat box between top side 6 and underside 8 which form the flat sides of the box. Carrier plate 4 contains a first printed circuit board plane 10a which is arranged on top side 6, a second conductor track plane 10b which is arranged on underside 8, and a further conductor track plane 10c which runs between planes 10a and 10b, that is to say inside carrier plate 4, and is indicated using dashed lines in FIG. 1. All of the conductor track planes 10a-c are each at a distance from one another in the normal direction of the printed circuit board 2, that is to say in the direction from the underside 8 to the top side 6.

Printed circuit board 2 also contains an electrical circuit 12 comprising components 14 and conductor tracks 16a-c arranged on top side 6. Circuit 12 also includes plated-through holes 17 which connect components 14 and conductor tracks 16a-c. Conductor track 16a is in conductor track plane 10a, that is to say on top side 6. Conductor track 16b is on conductor track plane 10b, that is to say on underside 8, and conductor track 16c is on conductor track plane 10c, that is to say in the middle or interior of carrier plate 4. For the sake of clarity, only part of circuit 12 is illustrated in FIG. 1.

Circuit 12 occupies a volume section 18 of printed circuit board 2, indicated in FIG. 1 by a dash-dotted line, in particular on top side 6. Section 18 also extends vertically from the partial surface of top side 6 into the volume of the carrier plate 4.

Printed circuit board 2 also contains a screen 20 according to the invention, only a section of which is shown in FIG. 1 for the sake of clarity. Screen 20 comprises a first screening conductor track 22a which is arranged on first conductor track plane 10a and surrounds substantially the entire section 18 on conductor track plane 10a. Screen 20 also comprises a second screening conductor track 22b which likewise surrounds section 18 on underside 8. In a circumferential region 24 which is congruent with screening conductor tracks 22a and 22b in this case and likewise surrounds section 18, screening conductor tracks 22a, b are congruent, that is to say are shifted with respect to one another only in the direction of the perpendicular to the flat sides, i.e., the abovementioned normal direction. Screen 20 also comprises a plurality of plated-through holes 26 which each electrically connect screening conductor tracks 22a, b to one another and penetrate carrier plate 4 for this purpose. All of the plated-through holes 26 also surround section 18.

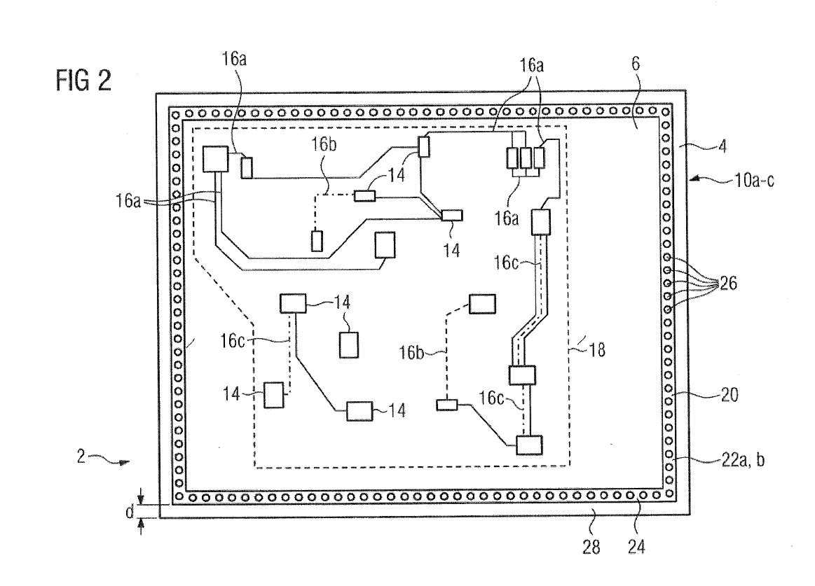

FIG. 2 shows printed circuit board 2 from FIG. 1 in the direction of the arrow II, i.e., in a plan view of top side 6. To illustrate the different conductor track planes 10a-c, conductor tracks 16a respectively lying in these planes are illustrated here using solid lines, conductor tracks 16b are illustrated using dashed lines and conductor tracks 16c are illustrated using dash-dotted lines. Section 18 and the entire screen 20 which is also arranged in edge region 28 of printed circuit board 2 in FIGS. 1 and 2 can be seen more clearly again in FIG. 2. Screen 20 is thus at a short, approximately constant distance d from the edge of printed circuit board 2, for example d≈1 mm. Screening conductor tracks 22a, b are congruent and again simultaneously surround circumferential region 24.

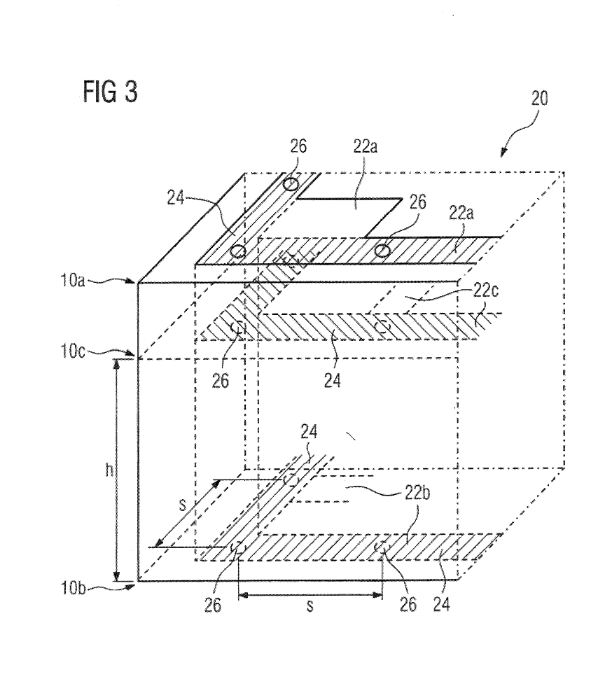

FIG. 3 shows an alternative embodiment of a screen 20, in which case, for the sake of clarity, plated-through holes 26 are indicated here only by means of circles which represent their intersections with screening conductor tracks 22a-c. FIG. 3 also shows that screen 20 comprises a further screening conductor track 22c which is on an intermediate plane, namely the conductor track plane 10c, i.e., inside carrier plate 4. Screening conductor tracks 22a-c are not congruent in this case. Screening conductor track 22a has a square form which extends inwards, for example in the corner illustrated. Screening conductor tracks 22b, c each comprise a branch which leads to the interior of printed circuit board 2. The three screening conductor tracks 22a-c are congruent only in a hatched circumferential region 24. However, plated-through holes 26 are solely in circumferential region 24 since they always reach and make contact with all three screening conductor tracks 22a-c there.

The distances s between two plated-through holes 26 in the longitudinal direction of circumferential region 24 correspond in this case to the distance h between conductor track planes 10b and 10c and 10a and 10b, i.e., to the entire thickness of printed circuit board 2.

In FIGS. 1-3, screens 20 completely encircle edge region 28 of printed circuit board 2, i.e., they surround the entire printed circuit board 2.

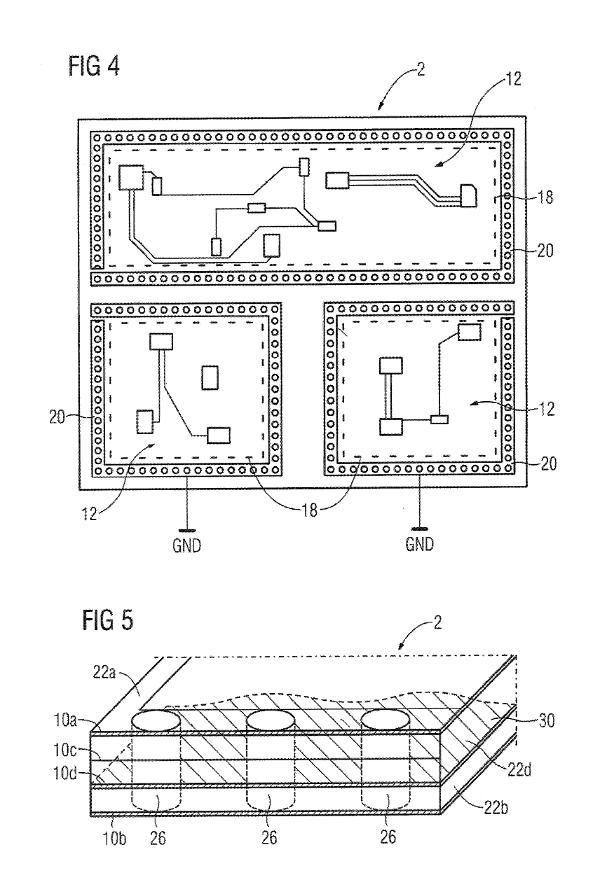

FIG. 4 shows an alternative printed circuit board 2 comprising three different circuits 12. The three circuits 12 are intended to be screened from interference to avoid respective undesirable EMC events in circuits 12. Each circuit 12 occupies its own section 18 of printed circuit board 2. Each section 18 is therefore surrounded by its own screen 20 which respectively corresponds to the screens from FIGS. 1-3. In this case, the individual screens 20 thus encircle a respective section 18 but not the entire printed circuit board 2.

In FIG. 4, the upper large screen 20 shown is also completely insulated as a screen 20 which is freely floating in terms of its potential. It is not conductively connected to any other potential. However, the two smaller screens 20 in the lower region of FIG. 4 are each conductively connected to a ground potential GND, with the result that these two screens 20 are likewise at ground potential GND.

FIG. 5 shows a perspective section through an alternative printed circuit board 2 which contains a fourth conductor track plane 10d. In this case, the entire conductor track plane 10d is in the form of a continuous ground layer 30 which covers the entire printed circuit board 2. The only exceptions here are smaller openings (not illustrated) in the ground layer 30, through which signal-carrying lines (not illustrated) are passed in an insulated manner. Ground layer 30 is also connected to the plated-through holes 26 and thus belongs to screen 20. Ground layer 30 is thus likewise a screening conductor track 22d which effects particularly good EMC screening of printed circuit board 2.

In an alternative embodiment, the screening conductor track 22a also forms a further ground layer 30 in FIG. 5. The conductor tracks of the conductor track plane 10c which are signal-carrying conductor tracks are then completely surrounded on all spatial sides or in a three-dimensional manner by screen 20 in the form of two ground layers 30 in conductor track planes 10a, d and plated-through holes 26.

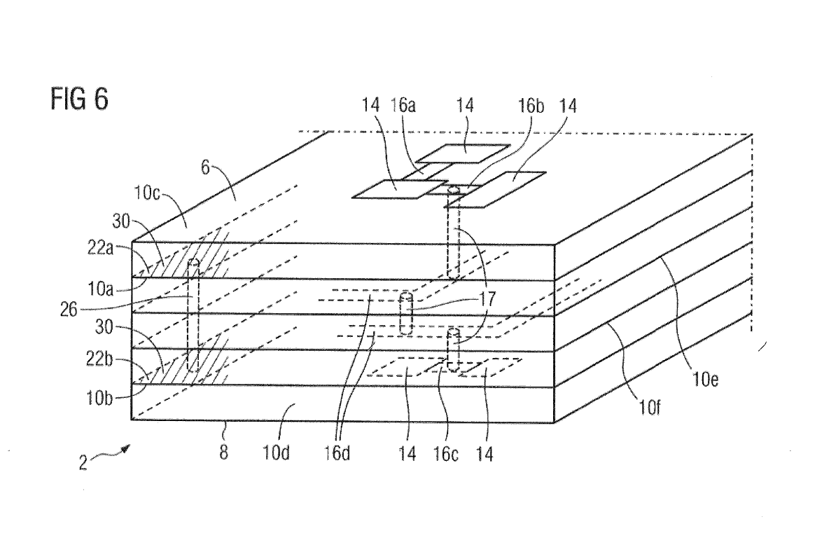

FIG. 6 shows another printed circuit board 2 with a total of six layers, conductor track planes 10a-f. Conductor track planes 10a, b as the uppermost and lowermost inner layers contain two screening conductor tracks 22a, b, respectively, which are in the form of ground layers 30 here, i.e., they have degenerated to form ground layers 30 (indicated by hatching). Conductor track planes 10c, d are on top side 6 and underside 8 and bear components 14 and only short conductor tracks 16a-c of circuit 12 which are not critical with respect to interference. In contrast, the conductor track planes 10e, f bear the actual conductor tracks 16d of circuit 12. Screening conductor tracks 22a, b, i.e., ground layers 30 and connecting plated-through holes 26, again form screen 20 which completely encloses the two circuit layers here, i.e., conductor track planes 10e, f, and screens them from interference.

Thus, while there have shown and described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

What is claimed is:

1. A printed circuit board comprising:
a generally box-like carrier plate having a top side and an underside;
at least a first and second conductor track planes separated by a first distance;
an electrical circuit on at least one section of said carrier plate;
a screen which screens said circuit from electromagnetic interference, said screen containing a first screening conductor track which is arranged on said first conductor track plane and substantially completely surrounds said at least one section; and
a second screening conductor track which is arranged on said second conductor track plane and also substantially completely surrounds said at least one section;
wherein said first and second screening conductor tracks are substantially congruent at least in a circumferential region which surrounds said circuit; and
wherein said screen contains, in said circumferential region, a plurality of plated-through holes which penetrate said carrier plate and which connect said first and second screening conductor tracks.

2. The printed circuit board of claim 1, in which said first conductor track plane is arranged on said top side of said carrier plate and said second conductor track plane is arranged on said underside thereof.

3. The printed circuit board of claim 1, having at least a third conductor track plane which is arranged between said first and second conductor track planes and which contains a third screening conductor track which corresponds to said first and second screening conductor tracks and is likewise connected to said plated-through holes.

4. The printed circuit board of claim 3, in which at least one of said screening conductor tracks is part of a ground layer which fills substantially all of said surface of said at least one section.

5. The printed circuit board of claim 1, wherein said screen is arranged in an edge region of said printed circuit board and substantially completely encircles the printed circuit board.

6. The printed circuit board of claim 1, in which said screen is connected to a ground potential.

7. The printed circuit board of claim 1, having a plurality of electrical circuits which each occupy a respective section of said carrier plate, in which each of said plurality of electrical circuits has a respective screen which substantially completely surrounds its respective circuit.

8. The printed circuit board of claim 1, having at least two adjacent plated-through holes which are separated by a second distance which is no less than about said first distance.
